(19) United States
(12) Patent Application Publication
(10) Pub. No.: US 2018/0166306 A1
(43) Pub. Date: Jun. 14, 2018

(54) QUARTZ CRYSTAL MICROBALANCE UTILIZATION FOR FORELINE SOLIDS FORMATION QUANTIFICATION

(71) Applicant: Applied Materials, Inc., Santa Clara, CA (US)

(72) Inventors: David Muquing HOU, Cupertino, CA (US); James L'HEUREUX, Santa Clara, CA (US); Zheng YUAN, Santa Clara, CA (US)

(21) Appl. No.: 15/826,063

(22) Filed: Nov. 29, 2017

Related U.S. Application Data
(60) Provisional application No. 62/432,071, filed on Dec. 9, 2016.

(51) Int. Cl. H01L 21/67; C23C 16/50; C23C 16/24; C23C 14/48

(52) U.S. Cl. CPC H01L 21/67253; C23C 14/48; C23C 16/24; C23C 16/50

(57) ABSTRACT

Embodiments of the present disclosure generally relate to abatement for semiconductor processing equipment. More particularly, embodiments of the present disclosure relate to techniques for foreline solids formation quantification. In one embodiment, a system includes one or more quartz crystal microbalance (QCM) sensors located between a processing chamber and a facility exhaust. The one or more QCM sensors provide real-time measurement of the amount of solids generated in the system without having to shut down a pump located between the processing chamber and the facility exhaust. In addition, information provided by the QCM sensors can be used to control the flow of reagents used to abate compounds in the effluent exiting the processing chamber in order to reduce solid formation.

### CROSS-REFERENCE TO RELATED APPLICATIONS

This application claims priority to U.S. Provisional Patent Application Ser. No. 62/432,071, filed on Dec. 9, 2016, which herein is incorporated by reference.

### BACKGROUND

### Field

Embodiments of the present disclosure generally relate to abatement for semiconductor processing equipment. More particularly, embodiments of the present disclosure relate to techniques for foreline solids formation quantification.

### Description of the Related Art

Effluent produced during semiconductor manufacturing processes includes many compounds which are abated or treated before disposal, due to regulatory requirements and environmental and safety concerns. Among these compounds are PFCs and halogen containing compounds, which are used, for example, in etching or cleaning processes.

PFCs, such as CF₄, C₂F₆, NF₃ and SF₆, are commonly used in the semiconductor and flat panel display manufacturing industries, for example, in dielectric layer etching and chamber cleaning. Following the manufacturing or cleaning process, there is typically a residual PFC content in the effluent gas stream pumped from the process chamber. PFCs are difficult to remove from the effluent stream, and their release into the environment is undesirable because they are known to have relatively high greenhouse activity. Remote plasma sources (RPS) or in-line plasma sources (IPS) have been used for abatement of PFCs and other global warming gases.

The design of current abatement technology for abating PFCs utilizes a reagent to react with PFCs. However, solid particles can generate in the RPS, exhaust line and pump downstream of the RPS as a result of the plasma abatement or of the process chemistry in the process chamber. The solids can cause pump failure and foreline clogging if ignored. In some cases, the solids are highly reactive which can present safety concerns. Conventionally, detection of the solids formation is done by breaking vacuum and halting the pump to physically inspect the foreline or any installed traps. This detection process includes a planned maintenance during which the process chamber is non-operational and can only provide feedback on the type and amount of solids every few weeks. In addition, if the solids are reactive, it may be dangerous to open the foreline without prior knowledge of the quantity of the solids buildup in the foreline.

Therefore, an improved apparatus is needed.

### SUMMARY

Embodiments of the present disclosure generally relate to abatement for semiconductor processing equipment. In one embodiment, a foreline assembly includes a plasma source, a first conduit coupled to the plasma source, wherein the first conduit is upstream of the plasma source, a second conduit located downstream of the plasma source, and a quartz crystal microbalance sensor disposed in the second conduit.

In another embodiment, a vacuum processing system includes a vacuum processing chamber having an exhaust port, a vacuum pump, and a foreline assembly coupled to the vacuum processing chamber and the vacuum pump, wherein the foreline assembly includes a first conduit coupled to the exhaust port of the vacuum processing chamber, a plasma source coupled to the first conduit, a second conduit coupled to the vacuum pump, wherein the second conduit is located downstream of the plasma source, and a first quartz crystal microbalance sensor disposed in the second conduit.

In another embodiment, a method includes flowing an effluent from a processing chamber into a plasma source, flowing one or more abatement reagents into a foreline assembly, monitoring an amount of solids accumulated downstream of the plasma source using a first quartz crystal microbalance sensor, and adjusting flow rates of the one or more abatement reagents based on information provided by the first quartz crystal microbalance sensor.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A is a schematic diagram of a vacuum processing system according to one embodiment described herein.

FIG. 1B is a schematic diagram of a portion of the vacuum processing system including two quartz crystal microbalance sensors, according to one embodiment described herein.

FIG. 2 is a flow diagram illustrating a method for abating effluent from a processing chamber, according to one embodiment described herein.

To facilitate understanding, identical reference numerals have been used, wherever possible, to designate identical elements that are common to the Figures Additionally, elements of one embodiment may be advantageously adapted for utilization in other embodiments described herein.

### DETAILED DESCRIPTION

Embodiments of the present disclosure generally relate to abatement for semiconductor processing equipment. More particularly, embodiments of the present disclosure relate to techniques for foreline solids formation quantification. In one embodiment, a system includes one or more quartz crystal microbalance (QCM) sensors located between a processing chamber and a facility exhaust. The one or more QCM sensors provide real-time measurement of the amount of solids generated in the system without having to shut down a pump located between the processing chamber and the facility exhaust. In addition, information provided by the QCM sensors can be used to control the flow of reagents used to abate compounds in the effluent exiting the processing chamber in order to reduce solid formation.

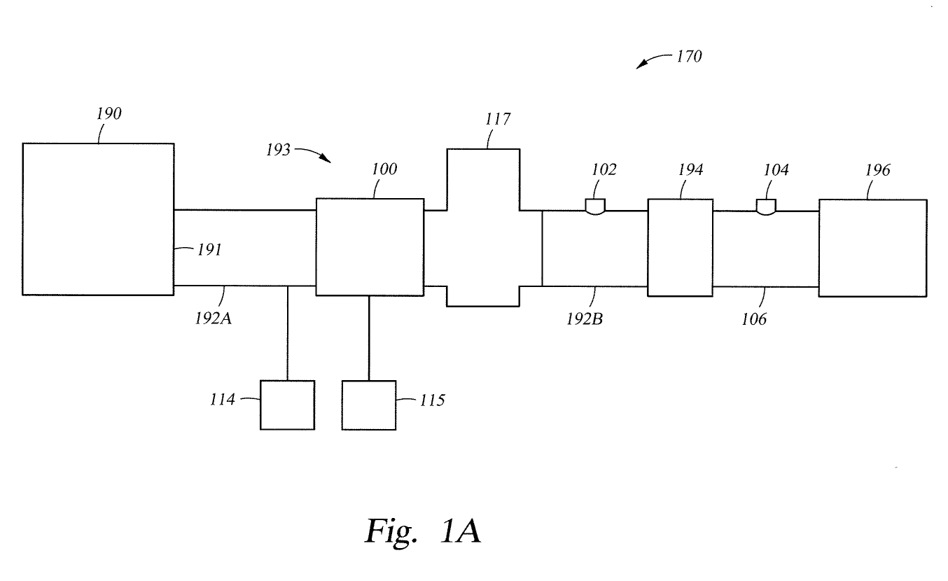

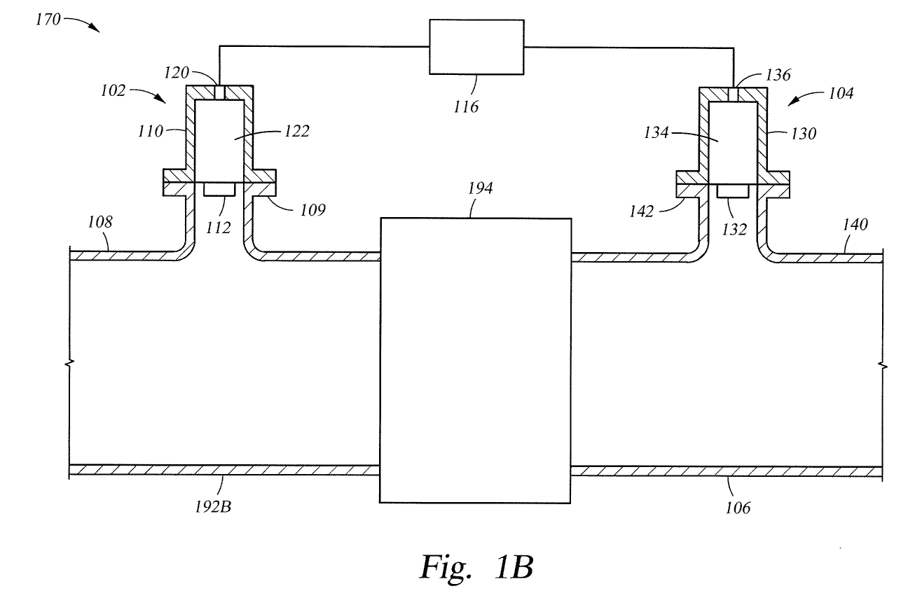

FIG. 1A is a schematic side view of a vacuum processing system 170. The vacuum processing system 170 includes at least a vacuum processing chamber 190, a vacuum pump 194, and a foreline assembly 193 coupled to the vacuum processing chamber 190 and the vacuum pump 194. The vacuum processing chamber 190 is generally configured to perform at least one integrated circuit manufacturing process, such as a deposition process, an etch process, a plasma treatment process, a preclean process, an ion implant process, or other integrated circuit manufacturing process. The process performed in the vacuum processing chamber 190 may be plasma assisted. For example, the process performed in the vacuum processing chamber 190 may be plasma deposition process for depositing a silicon-based material. The foreline assembly 193 includes at least a first conduit 192A coupled to a chamber exhaust port 191 of the vacuum processing chamber 190, a plasma source 100 coupled to the first conduit 192A, a second conduit 192B coupled to the vacuum pump 194, and a QCM sensor 102 disposed in the second conduit 192B. The first conduit 192A and the second conduit 192B may be referred to as the foreline. The second conduit 192B is located downstream of the plasma source 100, and the QCM sensor 102 is located at a location downstream of the plasma source 100.

One or more abatement reagent sources 114 are coupled to foreline assembly 193. In some embodiments, the one or more abatement reagent sources 114 are coupled to the first conduit 192A. In some embodiments, the one or more abatement reagent sources 114 are coupled to the plasma source 100. The abatement reagent sources 114 provide one or more abatement reagents into the first conduit 192A or the plasma source 100 which may be energized to react with or otherwise assist converting the materials exiting the vacuum processing chamber 190 into a more environmentally and/or process equipment friendly composition. In some embodiments, one or more abatement reagents include water vapor, an oxygen containing gas, such as oxygen gas, and combinations thereof. Optionally, a purge gas source 115 may be coupled to the plasma source 100 for reducing deposition on components inside the plasma source 100.

The foreline assembly 193 may further include an exhaust cooling apparatus 117. The exhaust cooling apparatus 117 may be coupled to the plasma source 100 downstream of the plasma source 100 for reducing the temperature of the exhaust coming out of the plasma source 100.

The QCM sensor 102 may be disposed in the second conduit 192B that is located downstream of the plasma source 100. The QCM sensor 102 may be a distance away from the plasma source 100 so noise from the thermal and plasma effects is minimized. The vacuum processing system 170 may further includes a conduit 106 coupled to the vacuum pump 194 to the facility exhaust 196. The facility exhaust 196 generally includes scrubbers or other exhaust cleaning apparatus for preparing the effluent of the vacuum processing chamber 190 to enter the atmosphere. In some embodiments, a second QCM sensor 104 is disposed in the conduit 106 that is located downstream of the vacuum pump 194. The QCM sensors 102, 104 provide real-time measurement of the amount of solids generated in the vacuum processing system 170 and accumulated downstream of the plasma source 100 without having to shut down the vacuum pump 194. In addition, the quantity of solids formed in the vacuum processing system 170 and accumulated downstream of the plasma source 100 provided by the QCM sensors 102, 104 can be used to control the flow of abatement reagents in order to reduce solid formation and eliminate solids in the vacuum processing system 170.

FIG. 1B is a schematic diagram of a portion of the vacuum processing system 170 including the QCM sensors 102, 104 according to one embodiment described herein. As shown in FIG. 1B, the second conduit 192B includes a wall 108 and a flange 109 formed in the wall 108. The QCM sensor 102 is coupled to the flange 109. The QCM sensor 102 includes a sensor element 112 and a body 110 enclosing a region 122. The sensor element 112 is a quartz crystal having a metal coating. Electronic sensor components are located in the region 122. In order to prevent corrosive compounds in the second conduit 192B from entering the region 122 of the QCM sensor 102, a purge gas is flowed into the region 122 from a purge gas source 116 via a purge gas injection port 120 formed in the body 110. The purge gas may be any suitable purge gas, such as nitrogen gas. During operation, the sensor element 112 is excited by an electrical current at a very high frequency, and as solids deposit on the surface of the sensor element 112, the frequency changes. The amount of solids deposited on the surface can be measured by measuring the change in the frequency. The metal coating of the sensor element 112 can promote the adherence of the solids deposition on the sensor element 112. In one embodiment, the metal coating is aluminum. In another embodiment, the metal coating is gold. The sensor element 112 having the metal coating is recessed from the flow path of the compounds exiting the plasma source 100 in order to reduce the risk of metal migration back to the vacuum processing chamber 190.

In some embodiments, in addition to the QCM sensor 102, the second QCM sensor 104 is utilized. As shown in FIG. 1B, the conduit 106 includes a wall 140 and a flange 142 formed in wall 140. The second QCM sensor 104 is coupled to the flange 142. The second QCM sensor 104 includes a sensor element 132 and a body 130 enclosing a region 134. The sensor element 132 is a quartz crystal having a metal coating. Electronic sensor components are located in the region 134. In order to prevent corrosive compounds in the conduit 106 from entering the region 134 of the second QCM sensor 104, a purge gas is flowed into the region 134 from the purge gas source 116 via a purge gas injection port 136 formed in the body 130. In some embodiments, the purge gas is generated in a separate purge gas source. The purge gas may be any suitable purge gas, such as nitrogen gas. The second QCM sensor 104 may operate under the same principle as the QCM sensor 102. The metal coating of the sensor element 132 of the second QCM sensor 104 may be the same as the metal coating of the sensor element 112 of the QCM sensor 102. The sensor element 132 having the metal coating is recessed from the flow path of the compounds exiting the plasma source 100 in order to reduce the risk of metal migration back to the vacuum processing chamber 190.

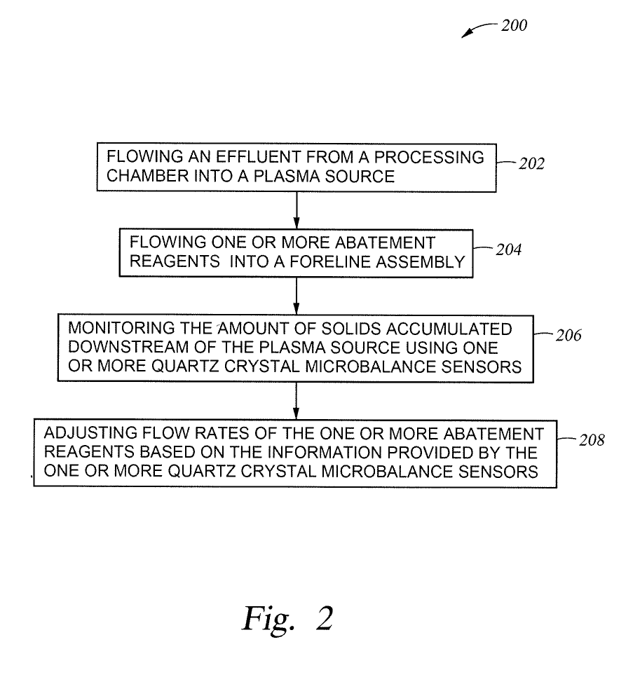

FIG. 2 is a flow diagram illustrating a method 200 for abating effluent from a processing chamber, according to one embodiment described herein. The method 200 starts at block 202 by flowing an effluent from a processing chamber, such as the vacuum processing chamber 190 shown in FIG. 1A, into a plasma source, such as the plasma source 100 shown in FIG. 1A. The effluent may include a PFC or a halogen containing compound, such as SiF₄. At block 204, the method continues by flowing one or more abatement reagents into a foreline assembly, such as the first conduit 192A or the plasma source 100 of the foreline assembly 193 shown in FIG. 1A. The abatement reagents may be water vapor or water vapor and oxygen gas. At block 206, solids are generated as the plasma source performs the abatement process, and the amount of solids accumulated downstream of the plasma source is monitored using one or more QCM sensors, such as the QCM sensors 102, 104 shown in FIG. 1A. In one embodiment, one QCM sensor is utilized to monitor the amount of solids accumulated downstream of the plasma source, and the QCM sensor is the QCM sensor 102 shown in FIG. 1A. In another embodiment, two QCM sensors are utilized to monitor the amount of solids accumulated downstream of the plasma source, and the two QCM sensors are QCM sensors 102, 104 shown in FIG. 1A. The QCM sensors provide real-time measurement of the amount of solids generated in the vacuum processing system and accumulated downstream of the plasma source without having to shut down the vacuum pump 194. In addition, an operator can use the information provided by the one or more QCM sensors to determine whether the foreline can be opened safely to perform maintenance on the components of the vacuum processing system.

Next, at block 208, flow rates of the one or more abatement reagents are adjusted based on the amount of solids accumulated downstream of the plasma source, which is provided by the one or more QCM sensors. For example, when a small amount of solids is detected by the one or more QCM sensors, the flow rate of water vapor is much greater than the flow rate of oxygen gas. In some embodiments, only water vapor is flowed into foreline assembly (first conduit 192A or the plasma source 100). When water vapor is used as an abatement reagent, the destruction and removal efficiency (DRE) of the PFCs is high, but solids are formed. As the one or more QCM sensors detect more solids accumulated in the foreline assembly downstream of the plasma source, the flow rate of the water vapor is reduced while the flow rate of the oxygen gas is increased. When oxygen gas is flowed into the foreline assembly (first conduit 192A or the plasma source 100), solids are eliminated, but the DRE of the PFCs is low. In addition, increased amount of oxygen gas flowed into the plasma source may corrode the core of the plasma source. In one embodiment, the flow rates of the water vapor and oxygen gas are adjusted so a ratio of the flow rate of the water vapor to the flow rate of the oxygen gas is three.

In other words, the flow rate of the oxygen gas increases as the one or more QCM sensors detect increased amount of solids accumulated downstream of the plasma source, and the flow rate of the oxygen gas decreases as the one or more QCM sensors detect decreased amount of solids accumulated downstream of the plasma source. However, the ratio of the flow rate of the water vapor to the flow rate of the oxygen gas should be three or less to prevent DRE from dropping to an unacceptable level. The flow rate of the water vapor may be adjusted along with adjusting the flow rate of the oxygen gas. In one embodiment, the flow rate of the oxygen gas is increased and the flow rate of the water vapor is decreased proportionally. In another embodiment, the flow rate of the oxygen gas is decreased and the flow rate of the water vapor is increased proportionally. In some embodiments, the flow rate of the water vapor remains constant while the flow rate of the oxygen gas is adjusted based on the amount of solids accumulated downstream of the plasma source.

By utilizing one or more QCM sensors in the vacuum processing system downstream of the plasma source, real-time measurement of the amount of solids generated in the system can be achieved. Having real-time measurement of the amount of solids generated in the system helps determine whether it is safe to open the foreline. In addition, real-time measurement of the amount of solids can be used to control the flow rates of one or more abatement reagents to abate compounds in the effluent exiting the processing chamber in order to reduce solid formation.

While the foregoing is directed to embodiments of the disclosed devices, methods and systems, other and further embodiments of the disclosed devices, methods and systems may be devised without departing from the basic scope thereof, and the scope thereof is determined by the claims that follow.

What is claimed is:

1. A foreline assembly, comprising:
a plasma source;
a first conduit coupled to the plasma source, wherein the first conduit is upstream of the plasma source;
a second conduit located downstream of the plasma source; and
a quartz crystal microbalance sensor disposed in the second conduit.

2. The foreline assembly of claim 1, further comprising an exhaust cooling apparatus coupled to the plasma source, wherein the second conduit is coupled to the exhaust cooling apparatus.

3. The foreline assembly of claim 1, wherein the second conduit includes a wall and a flange formed in the wall, wherein the quartz crystal microbalance sensor is coupled to the flange.

4. The foreline assembly of claim 1, wherein the quartz crystal microbalance sensor includes a body and a purge gas injection port formed in the body.

5. A vacuum processing system, comprising:
a vacuum processing chamber having an exhaust port;
a vacuum pump; and
a foreline assembly coupled to the vacuum processing chamber and the vacuum pump, wherein the foreline assembly comprises:
a first conduit coupled to the exhaust port of the vacuum processing chamber;
a plasma source coupled to the first conduit;
a second conduit coupled to the vacuum pump, wherein the second conduit is located downstream of the plasma source; and
a first quartz crystal microbalance sensor disposed in the second conduit.

6. The vacuum processing system of claim 5, wherein the foreline assembly further comprises an exhaust cooling apparatus coupled to the plasma source, wherein the second conduit is coupled to the exhaust cooling apparatus.

7. The vacuum processing system of claim 5, wherein the second conduit includes a wall and a flange formed in the wall, wherein the first quartz crystal microbalance sensor is coupled to the flange of the second conduit.

8. The vacuum processing system of claim 5, wherein the first quartz crystal microbalance sensor includes a body and a purge gas injection port formed in the body.

9. The vacuum processing system of claim 5, further comprising a third conduit coupled to the vacuum pump.

10. The vacuum processing system of claim 9, further comprising a second quartz crystal microbalance sensor disposed in the third conduit.

11. The vacuum processing system of claim 10, wherein the third conduit includes a wall and a flange formed in the wall, wherein the second quartz crystal microbalance sensor is coupled to the flange of the third conduit.

12. The vacuum processing system of claim 10, wherein the second quartz crystal microbalance sensor includes a body and a purge gas injection port formed in the body.

13. The vacuum processing system of claim 5, further comprising one or more abatement reagent sources coupled to the foreline assembly.

14. The vacuum processing system of claim 13, wherein the one or more abatement reagent sources are coupled to the first conduit.

15. The vacuum processing system of claim 13, wherein the one or more abatement reagent sources are coupled to the plasma source.

16. A method, comprising:
flowing an effluent from a processing chamber into a plasma source;
flowing one or more abatement reagents into a foreline assembly;
monitoring an amount of solids accumulated downstream of the plasma source using a first quartz crystal microbalance sensor; and
adjusting flow rates of the one or more abatement reagents based on information provided by the quartz crystal microbalance sensor.

17. The method of claim 16, wherein the one or more abatement reagents comprises water vapor and oxygen gas.

18. The method of claim 17, wherein adjusting flow rates of the one or more abatement reagents comprises increasing the flow rate of the oxygen gas when the amount of solids accumulated downstream of the plasma source increases and decreasing the flow rate of the oxygen gas when the amount of solids accumulated downstream of the plasma source decreases.

19. The method of claim 18, wherein adjusting flow rates of the one or more abatement reagents further comprises increasing the flow rate of the water vapor when the amount of solids accumulated downstream of the plasma source decreases and decreasing the flow rate of the water vapor when the amount of solids accumulated downstream of the plasma source increases.

20. The method of claim 18, wherein adjusting flow rates of the one or more abatement reagents further comprises maintaining the flow rate of the water vapor constant.
